(19) United States
(12) Patent Application Publication
(10) Pub. No.: US 2021/0323286 A1
(43) Pub. Date: Oct. 21, 2021

(54) ECO-FRIENDLY PACKAGING

(71) Applicant: DONGWON SYSTEMS CORPORATION, Seongnam-si (KR)

(72) Inventors: Sung Ji Choi, Ansan-si (KR); Jin Seok Choi, Pyeongtaek-si (KR); Do Yeon Kim, Suwon-si (KR)

(73) Assignee: DONGWON SYSTEMS CORPORATION, Seongnam-si (KR)

(21) Appl. No.: 17/192,184

(22) Filed: Mar. 4, 2021

(30) Foreign Application Priority Data
Apr. 21, 2020 (KR) 10-2020-0048077

(51) Int. Cl. B32B 27/08; B32B 27/32; B32B 33/00; B65D 33/24; B65D 81/24

(52) U.S. Cl. CPC B32B 27/08; B32B 27/32; B32B 33/00; B65D 33/24; B32B 2255/10; B32B 2439/46; B32B 2439/70; B32B 2255/26; B65D 81/245

(57) ABSTRACT

Disclosed is an eco-friendly packaging. The eco-friendly packaging with an accommodation space is formed by bonding multilayer films, and the multilayer films each include a first layer including a base layer including oriented polypropylene, and a coating layer applied to the outer surface of the base layer by coating, and a second layer laminated on the inner surface of the base layer, the second layer including cast polypropylene.

### CROSS-REFERENCE TO RELATED APPLICATION(S)

This application claims the benefit of Korean Patent Application No. 10-2020-0048077, filed on Apr. 21, 2020, in the Korean Intellectual Property Office, the disclosure of which is incorporated herein by reference.

### BACKGROUND

### 1. Field of the Invention

One or more example embodiments relate to an eco-friendly packaging.

### 2. Description of the Related Art

With the recently increasing consumption of instant food, recycling of disposable packaging containers that are discarded after eating food stored therein has emerged as an important issue in the protection of the environment.

In the past, a layer including aluminum was used in a packaging made of plastic to prevent decay of contents by securing gas and moisture barrier power. However, in the case of a packaging made of different types of materials, it was difficult to separate the packaging into the different materials and thus, difficult to recycle.

For example, when a packaging is made by stacking a layer of plastic such as polyethylene and a layer of aluminum, it was difficult to separate each of the layers constituting the packaging and difficult to reuse and recycle the packaging itself made of different materials.

However, unless a different material such as aluminum is used, it was difficult to secure sufficient impermeability against moisture and oxygen coming from the outside. Thus, it was difficult to prevent decay of contents, especially food, stored therein.

Therefore, there is a demand for developing a packaging that may secure eco-friendliness through easy recycling, while preventing damage to contents by securing a sufficient barrier function.

The above description has been possessed or acquired by the inventor(s) in the course of conceiving the present invention and is not necessarily an art publicly known before the present application is filed.

### SUMMARY

An aspect provides an eco-friendly packaging that is easy to recycle while having oxygen and moisture barrier power.

Another aspect also provides an eco-friendly packaging that is formed of a single material so as to be recycled.

According to an aspect, there is provided an eco-friendly packaging with an accommodation space, wherein the eco-friendly packaging may be formed by bonding multilayer films, and the multilayer films may each include a first layer including a base layer including oriented polypropylene, and a coating layer applied to the outer surface of the base layer by coating, and a second layer laminated on the inner surface of the base layer, the second layer including cast polypropylene.

The eco-friendly packaging may include a sealing part sealed along the circumference of the accommodation space, wherein the sealing part may be formed by bonding the second layers of the multilayer films.

The eco-friendly packaging may further include a virtual unsealing line for unsealing the accommodation space, and an unsealing part cut at the edge of the sealing part corresponding to the virtual unsealing line.

The eco-friendly packaging may further include an opening and closing part arranged on the inner surface thereof between the virtual unsealing line and the accommodation space, wherein the opening and closing part may be configured to selectively open and close the accommodation space.

The opening and closing part may include female and male fastening members that have length directions parallel to the virtual unsealing line, and are attached respectively to both sides of the inner surface of the eco-friendly packaging to fasten to each other, the accommodation space may be unsealed by cutting the eco-friendly packaging along the virtual unsealing line, and the unsealed accommodation space may be selectively opened and closed by fastening the female and male fastening members to each other.

The female and male fastening members may be formed of at least one of polypropylene or polyethylene.

The coating layer may be formed by coating the surface of the base layer with at least one of polyurethane dispersion (PUD) and polyvinyl alcohol (PVA).

The coating layer may be formed by depositing AlOx or SiOx on the surface of the base layer.

The multilayer films may have gas barrier properties of 0.1 to 0.5 cc/[m2-day] and have moisture barrier properties of 0.5 to 2.0 g/[m2-day].

Additional aspects of example embodiments will be set forth in part in the description which follows and, in part, will be apparent from the description, or may be learned by practice of the disclosure.

According to example embodiments, an eco-friendly packaging may be easy to recycle while having oxygen and moisture barrier power.

According to example embodiments, an eco-friendly packaging may be formed of a single material so as to be recycled.

The effects of the eco-friendly packaging are not limited to the above-mentioned effects, and other unmentioned effects can be clearly understood from the above description by those having ordinary skill in the technical field to which the present disclosure pertains.

### BRIEF DESCRIPTION OF THE DRAWINGS

The accompanying drawings illustrate preferred example embodiments of the present invention, and are provided together with the detailed description for better understanding of the technical idea of the present invention. Therefore, the present invention should not be construed as being limited to the example embodiments set forth in the drawings.

FIG. 1 is a plan view illustrating an eco-friendly packaging according to an example embodiment.

FIG. 2 is a cross-sectional view illustrating the eco-friendly packaging cut along the line II-II of FIG. 1.

FIG. 3 is a cross-sectional view illustrating the eco-friendly packaging cut along the line II-II of FIG. 1.

### DETAILED DESCRIPTION

Hereinafter, example embodiments will be described in detail with reference to the accompanying drawings. However, various alterations and modifications may be made to the example embodiments. Here, the example embodiments are not construed as limited to the disclosure. The example embodiments should be understood to include all changes, equivalents, and replacements within the idea and the technical scope of the disclosure.

The terminology used herein is for the purpose of describing particular example embodiments only and is not to be limiting of the example embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the example embodiments with reference to the accompanying drawings, like reference numerals refer to like constituent elements and a repeated description related thereto will be omitted. In the description of example embodiments, detailed description of well-known related structures or functions will be omitted when it is deemed that such description will cause ambiguous interpretation of the present disclosure.

Also, in the description of the components, terms such as first, second, A, B, (a), (b) or the like may be used herein when describing components of the present disclosure. These terms are used only for the purpose of discriminating one constituent element from another constituent element, and the nature, the sequences, or the orders of the constituent elements are not limited by the terms. When one constituent element is described as being “connected”, “coupled”, or “attached” to another constituent element, it should be understood that one constituent element can be connected or attached directly to another constituent element, and an intervening constituent element can also be “connected”, “coupled”, or “attached” to the constituent elements.

The same name may be used to describe an element included in the example embodiments described above and an element having a common function. Unless otherwise mentioned, the descriptions on the example embodiments may be applicable to the following example embodiments and thus, duplicated descriptions will be omitted for conciseness.

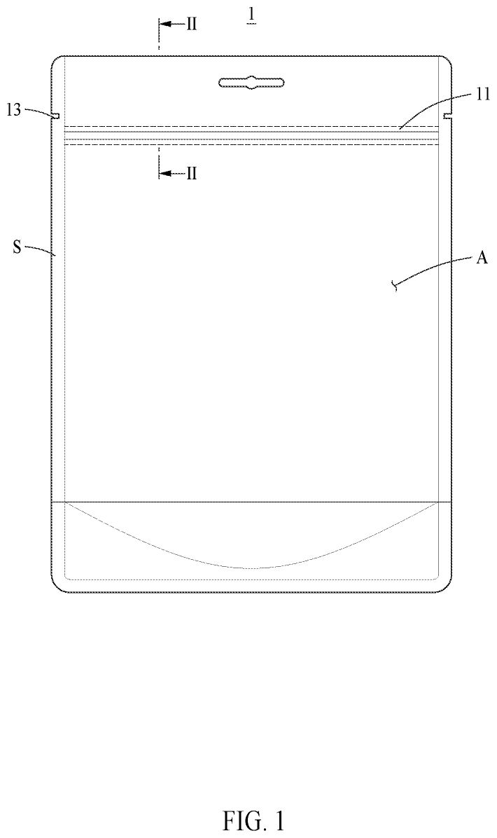

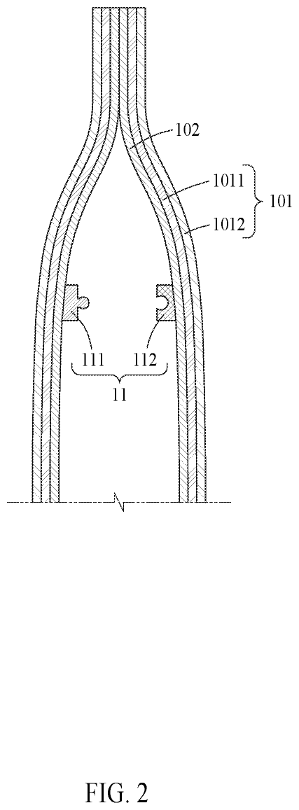

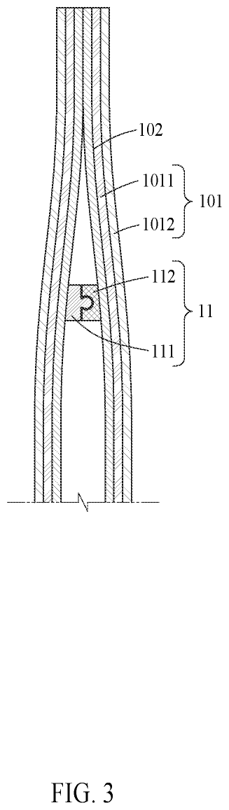

FIG. 1 is a plan view illustrating an eco-friendly packaging according to an example embodiment, FIG. 2 is a cross-sectional view illustrating the eco-friendly packaging cut along the line II-II of FIG. 1, and FIG. 3 is a cross-sectional view illustrating the eco-friendly packaging cut along the line II-II of FIG. 1.

Referring to FIGS. 1 to 3, an eco-friendly packaging 1 may be used to store an item. A packaging may include an accommodation space A for storing an item. For example, the packaging may store food in the accommodation space A. The packaging may be provided in the form of a disposable pouch for storing food.

The eco-friendly packaging 1 may be formed by bonding multilayer films. A multilayer film includes multiple layers, and the layers constituting the multilayer film may be formed of the same material. For example, the multilayer film may include a polypropylene-based material, and may be formed in a structure in which multiple functional layers are stacked. In this case, it is not necessary to separate the multilayer films constituting the eco-friendly packaging 1 into different materials during the disposal process after use, and thus a high recycling efficiency may be achieved.

Each multilayer film may include a first layer and a second layer.

The first layer may form the outer surface of the multilayer film, that is, the outer surface of the packaging. The first layer may include a base layer, and a coating layer applied to the outer surface of the base layer by coating.

The base layer may include a transparent material having high stability and durability, for example, oriented polypropylene (OPP). Information on the contents of the eco-friendly packaging 1 may be printed on the base layer. Since the base layer is formed of a transparent material, the printed information may be recognized outside.

The outer surface of the base layer may be coated with the coating layer. The coating layer may function as a barrier to protect the contents in the accommodation space A by blocking gas and moisture coming from the outside of the packaging. The coating layer may be formed by coating the surface of the base layer with polyurethane dispersion (PUD) or polyvinyl alcohol (PVA). Alternatively, the coating layer may be formed by depositing aluminum oxide (AlOx) or silicon oxide (SiOx) on the surface of the base layer.

Films of a different material such as aluminum thin films were used as multilayer films constituting a conventional packaging to prevent decay of an item stored therein. However, the packaging according to an example embodiment performs a gas and moisture barrier function through the coating layer applied to the surface of the base layer by coating. Thus, the eco-friendly packaging 1 itself may be recycled even without a separate process of separating a different material such as aluminum during the disposal process after use, whereby highly eco-friendly effects may be achieved.

The second layer may be stacked on the inner surface of the base layer. The second layer may refer to a packaging layer forming the inner surface of the packaging. In this case, the second layer may be formed of a polypropylene-based material, like the first layer. For example, the second layer may be formed of cast polypropylene (CPP).

The packaging is formed by bonding the multilayer films. In this case, the packaging may be formed by bonding the second layers of the multilayer films. In other words, the packaging may include a sealing part S that is sealed through the bonding of the multilayer films along the circumference of the accommodation space A, wherein the sealing part S may be formed by bonding the second layers of the multilayer films.

The accommodation space A of the packaging may be provided in a hermetically sealed state. That is, by forming the sealing part S on the circumference of the accommodation space A through bonding of the second layers as shown in FIG. 1, the packaging may be manufactured to have the accommodation space A that is hermetically sealed. In this case, the packaging may also have a virtual unsealing line for unsealing the accommodation space A. The unsealing line may be located above the accommodation space A. The packaging may include an unsealing part 13 cut near the edge of the sealing part S corresponding to the unsealing line. When a user applies a force to the unsealing part 13 in a direction of the unsealing line, the unsealing part 13 may guide the user to cut the packaging.

The packaging may include an opening and closing part 11 positioned between the unsealing line and the accommodation space A and configured to selectively open and close the unsealed accommodation space A.

The opening and closing part 11 may include female and male fastening members 111 and 112 attached to the inner surface of the packaging, that is, both sides of the inner surface of the packaging. The female and male fastening members 111 and 112 may have length directions parallel to the unsealing line, and selectively open and close the unsealed accommodation space A by fastening to each other. The female and male fastening members 111 and 112 may have shapes to fasten to each other, for example, shapes to couple to fit each other as shown in FIG. 2 or zipper shape. That is, the accommodation space A of the packaging may be provided in a hermetically sealed state at first. The accommodation space A may be unsealed by cutting the packaging along the unsealing line, and selectively opened and closed by fastening the female and male fastening members 111 and 112.

In this case, the female and male fastening members 111 and 112 may include at least one of polypropylene or polyethylene.

According to this structure, since the multilayer films and the opening and closing part 11 attached to the inner surfaces of the multilayer films are formed of the same material, the eco-friendly packaging 1 may be easy to recycle during the disposal process after use. In particular, the eco-friendly packaging 1 may implement functions such as a barrier function, a bonding function, and an item protection function through the first layers and the second layers constituting the multilayer films, implement a function to open and close the accommodation space A through the opening and closing part 11, and also secure highly eco-friendly effects as being formed of the same material.

Further, the eco-friendly packaging 1 may perform a barrier function to protect contents therein through the coating layer applied to the base layer by coating, without including a material different from that of the multilayer films, for example, an aluminum thin film layer. In this case, the eco-friendly packaging 1 may have gas permeability of 0.1 to 0.5 cc/[m2-day] and moisture barrier properties of 0.5 to 2.0 g/[m2-day], thereby securing a sufficient level of barrier efficiency.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents.

What is claimed is:

1. An eco-friendly packaging with an accommodation space, wherein the eco-friendly packaging is formed by bonding multilayer films, and
the multilayer films each comprise:
a first layer comprising a base layer including oriented polypropylene, and a coating layer applied to the outer surface of the base layer by coating; and
a second layer laminated on the inner surface of the base layer, the second layer including cast polypropylene.

2. The eco-friendly packaging of claim 1, comprising:
a sealing part sealed along the circumference of the accommodation space,
wherein the sealing part is formed by bonding the second layers of the multilayer films.

3. The eco-friendly packaging of claim 2, further comprising:
a virtual unsealing line for unsealing the accommodation space; and
an unsealing part cut at the edge of the sealing part corresponding to the virtual unsealing line.

4. The eco-friendly packaging of claim 3, further comprising:
an opening and closing part arranged on the inner surface thereof between the virtual unsealing line and the accommodation space,
wherein the opening and closing part is configured to selectively open and close the accommodation space.

5. The eco-friendly packaging of claim 4, wherein the opening and closing part comprises female and male fastening members that have length directions parallel to the virtual unsealing line, and are attached respectively to both sides of the inner surface of the eco-friendly packaging to fasten to each other,
the accommodation space is unsealed by cutting the eco-friendly packaging along the virtual unsealing line, and
the unsealed accommodation space is selectively opened and closed by fastening the female and male fastening members to each other.

6. The eco-friendly packaging of claim 5, wherein the female and male fastening members are formed of at least one of polypropylene or polyethylene.

7. The eco-friendly packaging of claim 6, wherein the coating layer is formed by coating the surface of the base layer with at least one of polyurethane dispersion (PUD) and polyvinyl alcohol (PVA).

8. The eco-friendly packaging of claim 6, wherein the coating layer is formed by depositing AlOₓ or SiOₓ on the surface of the base layer.

9. The eco-friendly packaging of claim 7, wherein the multilayer films have gas barrier properties of 0.1 to 0.5 cc/[m²-day] and have moisture barrier properties of 0.5 to 2.0 g/[m²-day].
